(19) United States
(12) Patent Application Publication
(10) Pub. No.: US 2026/0037694 A1
(43) Pub. Date: Feb. 5, 2026

(54) REINFORCEMENT LEARNING FOR DYNAMIC INVERSION CONTROL OF GAS TURBINE ENGINES

(71) Applicant: GENERAL ELECTRIC COMPANY, Cincinnati, OH (US)

(72) Inventors: Stefan J. Cafaro, Chapel Hill, NC (US); Justin E. Barton, North Huntingdon, PA (US)

(21) Appl. No.: 18/788,738

(22) Filed: Jul. 30, 2024

(51) Int. Cl. G06F 30/27

(52) U.S. Cl. CPC G06F 30/27

(57) ABSTRACT

There are provided systems and methods for inversion control of turbine engines. For example, there is provided a processor-implemented method that includes a processor and a memory. The memory includes instructions which, when executed by the processor, cause the system at least to perform: simulating, by a simulated state space model, a desired dynamic response based on the sensor data and a control input; inverting the desired dynamic response as output by the state space model; determining an error between a perceived dynamic response and the inverted desired dynamic response; correcting the state space model for the determined error based on updating the one or more model parameters using a machine learning network; generating the desired dynamics based on the updated state space model; and controlling the engine based on the state space model.

### TECHNICAL FIELD

The present disclosure relates to engine control. Particularly, the present disclosure relates to a system and a method for reinforcement learning for dynamic inversion control of gas turbine engines.

### BACKGROUND

Gas turbine engines are used in a wide variety of applications, such as power generation, aircraft, and various machinery. Gas turbine engines have long been pivotal in various industrial applications, particularly in aviation, power generation, and marine propulsion, owing to their remarkable efficiency and power-to-weight ratios. The evolution of gas turbine technology has witnessed significant advancements, from early designs to modern sophisticated configurations, optimizing performance, fuel efficiency, and environmental sustainability. Innovations in materials science, aerodynamics, combustion, and control systems have driven the development of gas turbines, enabling higher operating temperatures, reduced emissions, and enhanced reliability. As such, there is a need for improvements in gas engine turbine control systems.

### BRIEF DESCRIPTION OF THE DRAWINGS

A better understanding of the features and advantages of the disclosed technology will be obtained by reference to the following detailed description that sets forth illustrative aspects, in which the principles of the technology are utilized, and the accompanying drawings of which:

FIG. 1 illustrates a system for reinforcement learning for dynamic inversion control of a gas turbine engine, according to an exemplary aspect;

FIG. 2 is a block diagram of a controller of the system of FIG. 1, in accordance with one aspect;

FIG. 3 is a block diagram of a machine learning network with inputs and outputs of a machine learning network, in accordance with aspects of the present disclosure;

FIG. 4 is a diagram of layers of the machine learning network of FIG. 3, in accordance with aspects of the present disclosure;

FIG. 5 is a block diagram of a state space model of the system of FIG. 1 in accordance with one aspect;

FIG. 6 is a flow diagram for the method of inversion control of turbine engines using the system of FIG. 1 in accordance with one aspect;

FIG. 7 is a flow diagram for the method for updating the state space model in accordance with one aspect;

FIG. 8 is a graph illustrating an example of desired and measured thrust over time in accordance with one aspect;

FIG. 9 is a graph illustrating an example of desired and measured thrust over time along with an embedded model of FIG. 1 in accordance with one aspect;

FIG. 10 is a graph illustrating another example of desired and measured thrust over time along with an embedded model of FIG. 1 in accordance with one aspect;

FIG. 11 is a graph showing a chirp signal used with the system of FIG. 1 in accordance with one aspect; and

FIG. 12 is an example Bode response of the ABCD state space of the system of FIG. 1 in accordance with one aspect.

### DETAILED DESCRIPTION

Although this disclosure will be described in terms of specific aspects, it will be readily apparent to those skilled in this art that various modifications, rearrangements, and substitutions may be made without departing from the spirit of this disclosure.

For the purpose of promoting an understanding of the principles of this disclosure, reference will now be made to exemplary aspects illustrated in the drawings, and specific language will be used to describe the same. It will nevertheless be understood that no limitation of the scope of this disclosure is thereby intended. Any alterations and further modifications of the features illustrated herein, and any additional applications of the principles of this disclosure, as illustrated herein, which would occur to one skilled in the relevant art and having possession of this disclosure, are to be considered within the scope of this disclosure.

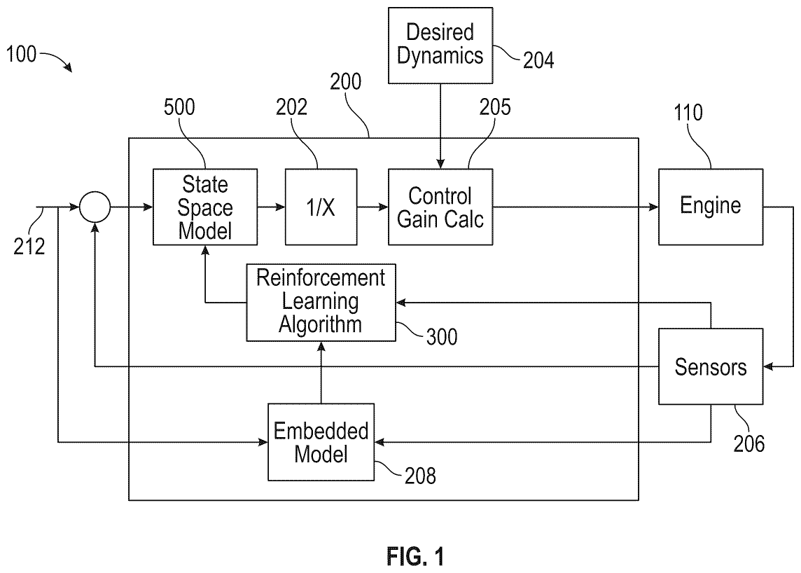

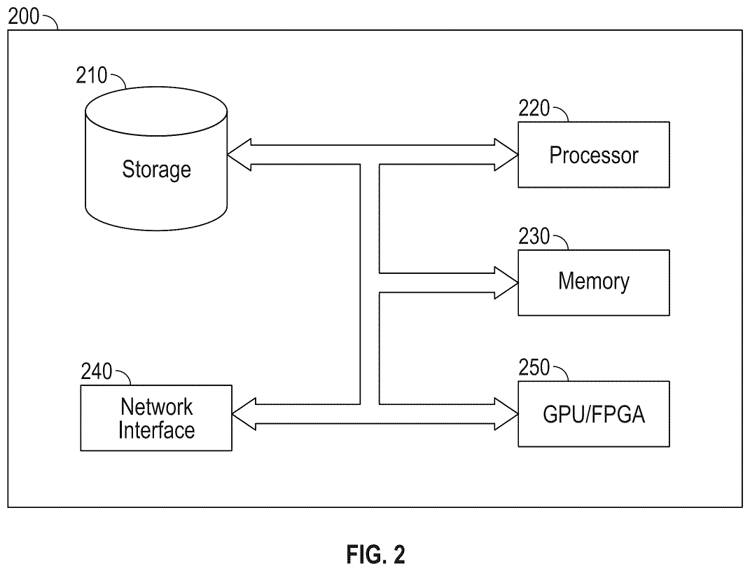

FIG. 1 illustrates an exemplary system 100 for inversion control of turbine engines. The system 100 generally includes one or more sensors 206 configured to generate sensor data indicative of a parameter of an engine 110, and a controller 200 (FIG. 2) configured to process the sensor data and a control input 212 using a linear state space model 500 and a machine learning network 400 to generate a control signal to the control the engine 110. In aspects, the controller may also execute an embedded model 208 that can be used as an input to the machine learning network 400. The linear state space model 500 is inverted 202 and used to cancel out engine dynamics. The controller then uses a specified dynamic response 204 as an input along with the inverted state space model 202 to perform a control gain calculation 205 and generate a control signal to control the engine (e.g., a parameter of the engine such as fan speed, or torque). The dynamic response 204 is specified as a desired second-order response given by a natural frequency and a damping ratio term.

The control inputs 212 may include, for example, fuel flow (e.g., WFM), pitch (e.g., fan pitch), variable stator vanes, inlet guide vanes, and/or electric power. The control signal output by the controller may include, for example, speed (e.g., fan speed or core speed), thrust, torque, and/or pressure ratios.

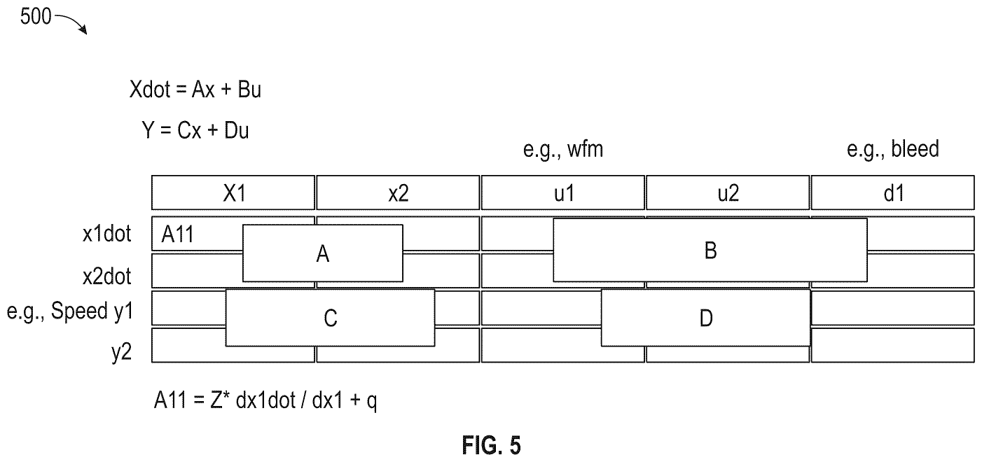

The system 100 provides the technical benefits of ensuring uniform response between engines, ensuring uniform response as an engine degrades, and improving stability margins for engine control. The system 100 provides these advantages over existing control systems in that the system 100 continuously updates and modifies the linear state space model in real time. The system 100 also provides the benefit of being able to be used to remove fan speed (N1) modifier and/or thrust modifier from the engine manufacturing process. During manufacturing, different fans generate different amounts of thrust at the same fan speed. Typically, an offset has to be determined and entered into a system to compensate. The system 100 is able to operate without the need for the fan speed offset by updating the parameters (FIG. 5) of the linear state space model 500 in real time.

Referring now to FIG. 2, exemplary components in the controller 200 in accordance with aspects of the present disclosure include, for example, a database 210, one or more processors 220, at least one memory 230, and a network interface 240. In aspects, the controller 200 may include a graphical processing unit (GPU) 250, which may be used for processing machine learning network models.

Database 210 can be located in storage. The term “storage” may refer to any device or material from which information may be capable of being accessed, reproduced, and/or held in an electromagnetic or optical form for access by a computer processor. Storage may be, for example, volatile memory such as RAM, non-volatile memory, which permanently holds digital data until purposely erased, such as flash memory, magnetic devices such as hard disk drives, and optical media such as a CD, DVD, Blu-ray Disc™, or the like.

In various aspects, data may be stored on controller 200, including, for example, user preferences, historical data, and/or other data. The data can be stored in database 210 and sent via the system bus to processor 220.

As will be described in more detail later herein, processor 220 executes various processes based on instructions that can be stored in the memory 230 and utilizing the data from database 210. With reference also to FIG. 1, a request from a user device, such as a mobile device or a client computer, can be communicated to the server through the server's network interface 240. The illustration of FIG. 2 is exemplary, and persons skilled in the art will be understood by other components that may exist in a controller 200. Such other components are not illustrated in FIG. 2 for clarity of illustration.

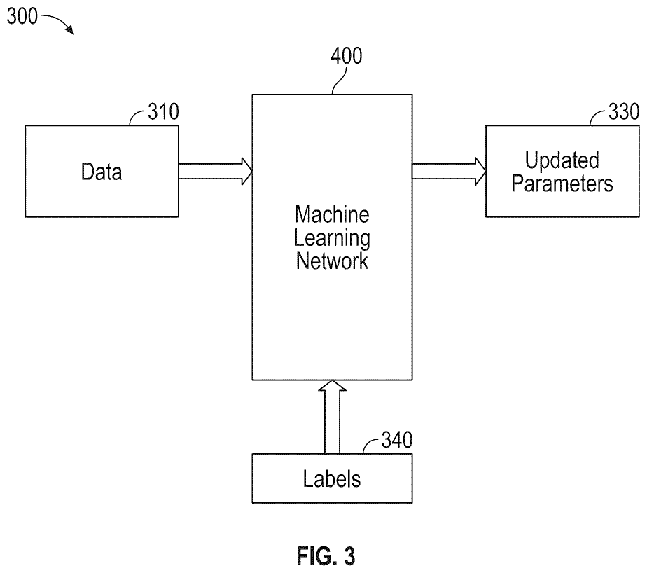

With reference to FIG. 3, a block diagram for a machine learning network 400 for classifying data in accordance with some aspects of the disclosure is shown. In some systems, a machine learning network 400 may include, for example, a convolutional neural network (CNN), a regression, and/or a recurrent neural network. A deep learning neural network includes multiple hidden layers. As explained in more detail below, the machine learning network 400 may leverage one or more classification models (e.g., CNNs, decision trees, a regression, Naive Bayes, k-nearest neighbor) to classify data. In aspects, the classification model 300 may use a data file 310 and labels 340 for classification. The machine learning network 400 may be executed on the controller 200 (FIG. 2). Persons of ordinary skill in the art will understand the machine learning network 400 and how to implement it.

In machine learning, a CNN is a class of artificial neural network (ANN). The convolutional aspect of a CNN relates to applying matrix processing operations to localized portions of data, and the results of those operations (which can involve dozens of different parallel and serial calculations) are sets of many features that are delivered to the next layer. A CNN typically includes convolution layers, activation function layers, deconvolution layers (e.g., in segmentation networks), and/or pooling (typically max pooling) layers to reduce dimensionality without losing too many features. Additional information may be included in the operations that generate these features. Providing unique information, which yields features that give the neural networks information, can be used to provide an aggregate way to differentiate between different data input to the neural networks.

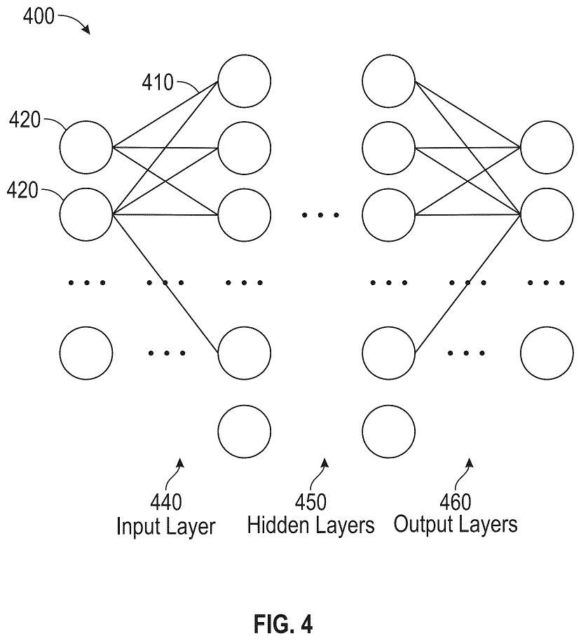

Referring to FIG. 4, generally, the machine learning network 400 (e.g., a convolutional deep learning neural network) includes at least one input layer 440, a plurality of hidden layers 450, and at least one output layer 460. The input layer 440, the plurality of hidden layers 450, and the output layer 460 all include neurons 420 (e.g., nodes). The neurons 420 between the various layers are interconnected via weights 410. Each neuron 420 in the machine learning network 400 computes an output value by applying a specific function to the input values coming from the previous layer. The function that is applied to the input values is determined by a vector of weights 410 and a bias. Learning, in the deep learning neural network, progresses by making iterative adjustments to these biases and weights. The vector of weights 410 and the bias are called filters (e.g., kernels) and represent particular features of the input (e.g., a particular shape). The machine learning network 400 may output logits. Although CNNs are used as an example, other machine learning classifiers are contemplated.

The machine learning network 400 may be trained based on labeling training data to optimize weights. For example, samples of feature data may be taken and labeled using other feature data. In some methods in accordance with this disclosure, the training may include reinforcement learning, supervised learning, or semi-supervised. Persons of ordinary skill in the art will understand training the machine learning network 400 and how to implement it.

FIG. 5 is a simplified block diagram of the linear state space model 500 of the system 100 of FIG. 1. The linear state space model 500 is a mathematical representation used to describe the behavior of a dynamic system over time. The linear state space model 500 consists of a set of first-order ordinary differential equations that relate the system's state variables to its inputs and outputs. The state variables represent the internal states of the system, such as position, velocity, or temperature, while the inputs are the external signals applied to the system, and the outputs are the measurable quantities produced by the system in response to those inputs. The linear state-space model is “linear” because the equations describing the system's dynamics are linear with respect to the state variables and inputs. x1 and x2 represent states of the linear state space model 500. u1 and u2 represent inputs of the linear state space model 500, for example, fuel flow (e.g., WFM), pitch (e.g., fan pitch), variable stator vanes, inlet guide vanes, and/or electric power. y1 and y2 represent outputs of the linear state space model 500, for example, speed (e.g., fan speed or core speed), thrust, torque, and/or pressure ratios. X1dot and X2dot are derivatives.

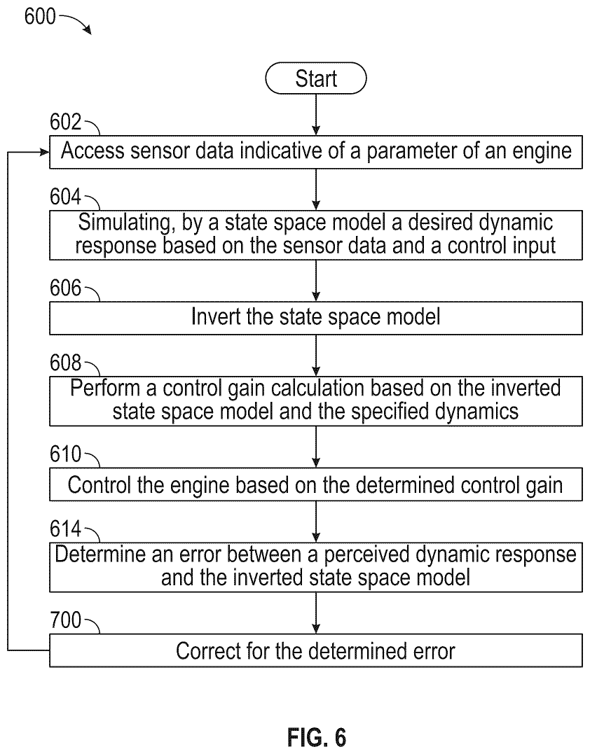

With reference to FIG. 6, a flow diagram for a method 600 for inversion control of turbine engines is shown. Although the steps of FIG. 6 are shown in a particular order, the steps need not all be performed in the specified order, and certain steps can be performed in another order. For example, FIG. 6 will be described below, with a controller 200 (FIG. 2) performing the operations. In various aspects, the operations of FIG. 6 may be performed all or in part by the controller 200 of FIG. 1. In aspects, the operations of FIG. 6 may be performed all or in part by another device, for example, a mobile device and/or a remote computer system. These and other variations are contemplated to be within the scope of the present disclosure.

Initially, at step 602, the controller 200 accesses sensor data indicative of a parameter of an engine 110. The sensor data sensed by the sensor 206 may include, for example, thrust, speed, power, torque, stall margin, and/or temperature of the engine 110.

At step 604, the controller 200 simulates, by a linear state space model 300, what the desired dynamic response should be based on the sensor data and a control input 212. The state space model 300 is a representation of the engine physics, which may be given as a collection of first-order linear differential equations captured in “Ax+Bu, Cx+Du” format. The ABCD matrix is inverted 202 and paired with the desired second-order response.

The state space model 300 generally includes one or more model parameters 300. The one or more model parameters 330 include partial derivatives (FIG. 5), of the state derivatives and/or control outputs with respect to state inputs and/or control inputs. The one or more model parameters 330 (FIG. 3) are configured to be updated.

The one or more model parameters 330 may be indicative of the engine physics most relevant to the control output, for example, the partial derivative of fuel flow to fan shaft acceleration in a case where a fuel controller and desired fan speed acceleration measurement are observed to be different from the linear model prediction. The control inputs may include, for example, fuel flow (e.g., WFM), pitch (e.g., fan pitch), variable stator vanes, inlet guide vanes, and/or electric power.

At step 606, the controller 200 inverts 202 (FIG. 1) (i.e., provides the reciprocal of) the linear state space model. The inverted linear state space model 202 and the specified dynamic response 204 are input into the control gain calculation 205.

At step 608, the controller 200 performs a control gain calculation 205 based on the inverted linear state space model 500 and the specified dynamic response 204, for example, the gain for fuel flow. The calculated control gain(s) are used to control the engine.

At step 610, the controller 200 controls the engine 110 based on the calculated control gain(s), for example, increasing or reducing fuel flow for a given control input.

At step 614, controller 200 determines an error between a measured dynamic response and the specified dynamic response 204 by taking the difference in the control output between the specified dynamic response 204 per the specified natural frequency and damping ratio term and comparing the difference to the measured response as reported by the sensors. The specified dynamic response 204 is typically specified as a desired second-order response given by a natural frequency and a damping ratio term, e.g., the shape of the response. Examples of desired response characteristics include rise time and/or overshoot. The specified dynamic response 204 may be determined by the control designer and is typically derived from a systems or aircraft level requirement, i.e., thrust response time.

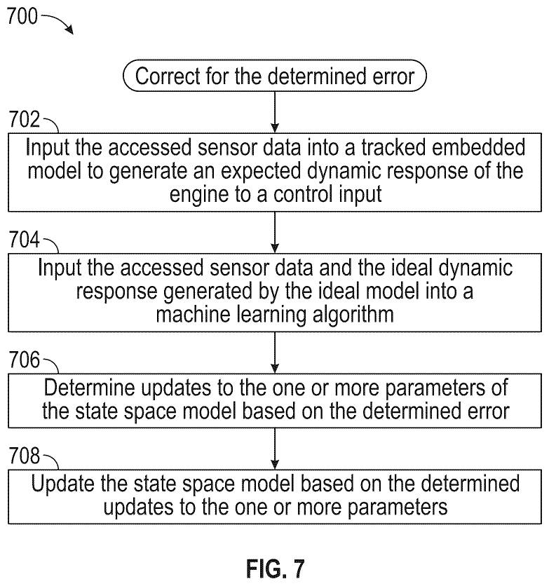

At method 700, the controller 200 corrects the state space model 500 for the determined error based on updating the one or more model parameters 330 (FIG. 3) using a machine learning network 400. Method 700 will be described in detail below in relation to FIG. 7. The machine learning network 400 may include gradient descent, an optimization function, and/or other machine learning.

System 100 is configured to iterate method 600 in order to obtain a response more like the one specified.

For example, a pilot may perform an engine burst. The resulting (measured dynamic response) engine response is compared to an ideal response (e.g., specified dynamic response 204) and found to be different to determine an error. The partial derivatives in the linear state space model inversion model are changed. Based on the error difference, the magnitude of the partial derivatives may be adjusted based on the magnitude of the error and a constraint variation about the nominal partial value. Rerunning the linearized state space model 500 enables the system 100 to determine if the adjustment was successful in reducing the observed error and iterative correction to minimize the error. The system 100 may tweak the partial derivatives in response to the remaining error. After a number of loops, the error tolerance threshold between the observed response and the ideal response is reached. Thus, the closer match is generated based on changing the partial derivatives and then a comparison shows whether any error remains, and the process continues.

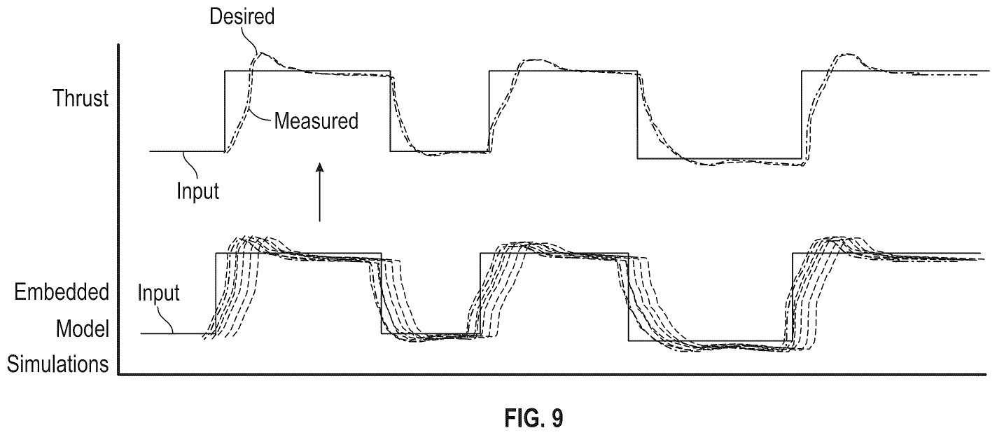

In another example, a pilot may command a small throttle increase (where the control input 212 may be fuel flow). Based on the commanded small throttle increase, the pilot may expect a small increase in engine thrust. The engine then may respond within a certain amount of overshoot (see FIG. 9). The system 100 observes the overshoot by accessing the sensor data, which includes thrust. The linear state space model 208, which is a proximation of what the dynamic response should be, looks at the sensor data (e.g., thrust) and the control input (e.g., fuel flow). The linear state space model 208 is inverted, and, along with the specified dynamic response 204 is used to calculate the gain to control the fuel flow. The controller sets the gains to control fuel flow based on the calculation. For example, there may be a reduction in the gain to control the fuel flow. The system 100 would observe the results and iterate to obtain a response more like the one specified.

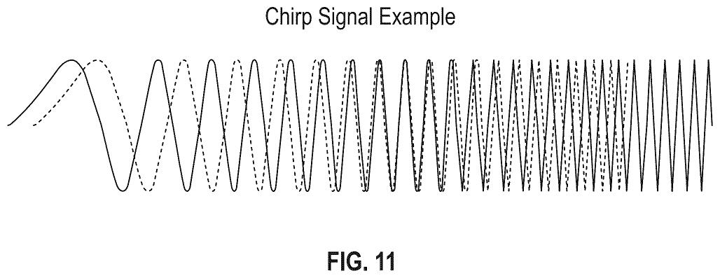

In aspects, the controller 200 may use a chirp to characterize the engine (FIG. 11). The controller 200 may generate a chirp signal in a desired effector to output a response. The desired effector is one or multiple control handles used to manipulate a desired output. For example, the desired effector may be fuel flow as an effector used to manipulate a fan speed response. In aspects, other variable geometries may be used as well to manipulate other outputs.

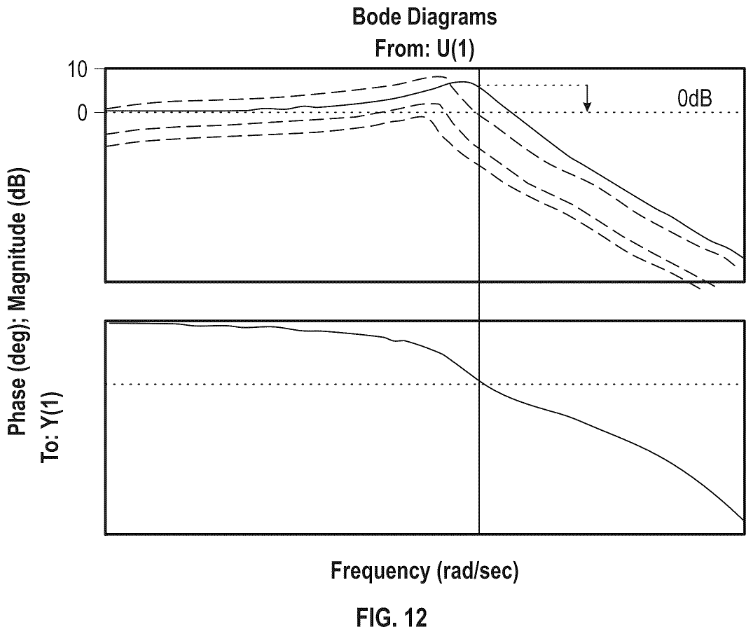

The controller 200 may generate Bode responses based on the output response (FIG. 12). In aspects, the controller 200 may tune the state space model 500 to achieve the desired dynamic response of at least one of actuator dynamics or fuel system dynamics based on the generated Bode responses.

In aspects, the controller 200 may perform periodic direct system identification using the generated Bode responses and generate a representation of plant dynamics of the engine based on the performed periodic direct system identification. In some aspects, the controller 200 may perform at least one of the following: fault detection or preventative maintenance based on the generated representation of the plant dynamics of the engine.

One example of fault detection or preventative maintenance would be if the desired dynamic response 330 for a fuel system to fan speed response deviated from the observed response above a certain threshold, either in time series response or in frequency analysis of the content from a chirp signal. This information could identify potential contamination or loss in efficiency of the fuel system (e.g., metering valve and/or bypass valve).

With reference to FIG. 7, a flow diagram for a method 700 for updating and/or correcting the state space model 500 is shown. Although the steps of FIG. 7 are shown in a particular order, the steps need not all be performed in the specified order, and certain steps can be performed in another order. For example, FIG. 7 will be described below, with a controller 200 (FIG. 2) performing the operations. In various aspects, the operations of FIG. 7 may be performed all or in part by the controller 200 of FIG. 1. In aspects, the operations of FIG. 7 may be performed all or in part by another device, for example, a mobile device and/or a remote computer system. These and other variations are contemplated to be within the scope of the present disclosure.

At step 702, the controller 200 inputs the accessed sensor data into a tracked embedded model 208 to generate an expected dynamic response of the engine to a control input. In aspects, the controller 200 may generate an expected dynamic response of the engine by the tracked embedded model 208, for example, a simulated burst to estimate the fan trajectory on a tracked model.

At step 704, the controller 200 inputs the accessed sensor data and the control input, into the machine learning network 400. For example, temperature, fuel flow, and pitch may be input into the tracked embedded model 208.

At step 706, the controller 200 determines, by the machine learning network, updates and/or corrections to the one or more model parameters of the state space model based on the determined error (from step 608).

At step 708, the controller 200 updates the state space model 500 based on the determined updated one or more model parameters. The one or more model parameters may include partial derivatives. For example, the partial derivatives of the state space model may be updated.

In another example, the method 700 for updating and/or correcting the state space model may not use the tracked embedded model 208. In aspects, the controller 200 may input the accessed sensor data, the control input, and the expected dynamic response generated by the expected model into a machine learning network 400. For example, to prepare the control inputs for the network the sensor data may be filtered. In aspects, the controller 200 may determine, by the machine learning network 400, updates to the one or more model parameters of the state space model 208 based on the determined error (from step 608). For example, if there are two to eight potential partial derivatives that could be used to explain the difference between the observed error and desired dynamic response 330, a machine learning network may be used to simultaneously tune different combinations of these partials and re-run the embedded model 208 to predict if a future response would optimally reduce the error.

In aspects, the controller 200 may update the linear state space model 500 based on the determined updated one or more model parameters 330 of the linear state space model 500. For example, the updated one or more model parameters 330 may include the magnitude of the partial derivatives which may be adjusted based on the magnitude of the error.

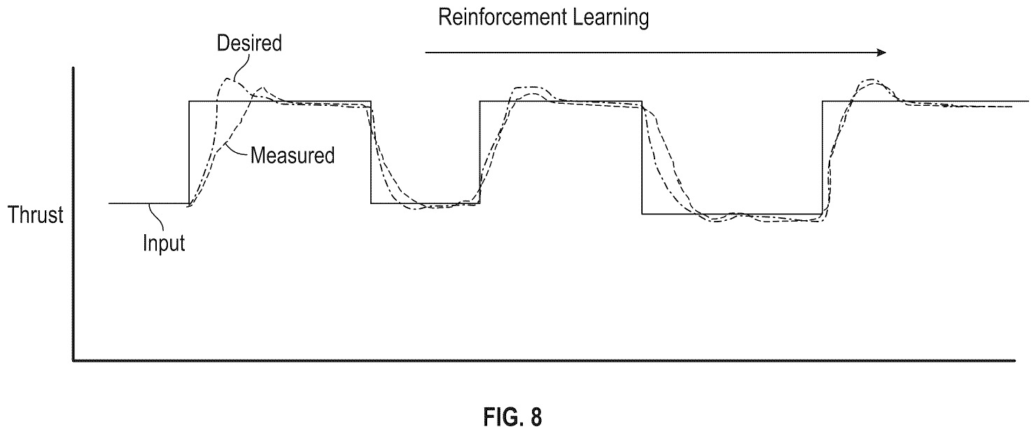

Referring to FIG. 8, a graph illustrating an example of desired dynamic response and measured dynamic response over time as corrected using reinforcement learning is shown. As the engine input signal rises the measured thrust lags. The system 100 of FIG. 1 processes the input signal and the measured signal to generate a desired dynamic response. For example, the input signal may be filtered to reduce noise and/or jitter. The difference between the desired and measured dynamic response is the error. Over time, this error is improved by reinforcement learning (machine learning network 400 of FIG. 1). The error is improved in part because the manipulation of the dynamic inversion state space model partial derivatives results in different controller gains being used to drive the control response. In this example, the same series of control inputs are maneuvers being performed by the aircraft in repetition over.

Referring to FIG. 9 is a graph illustrating an example of the desired dynamic response and the measured dynamic response over time along with the response provided by the embedded model 208 of FIG. 1. FIG. 9 expresses the power of using the embedded model 208 (FIG. 1) to improve the iterative loop and simulation capability to faster converge on a desired solution. The system 100 integrates out the error between the specified dynamic response 204 and the measured response using the embedded model 208 by feeding back the response to the state space model, which is used for inversion 202 (FIG. 1).

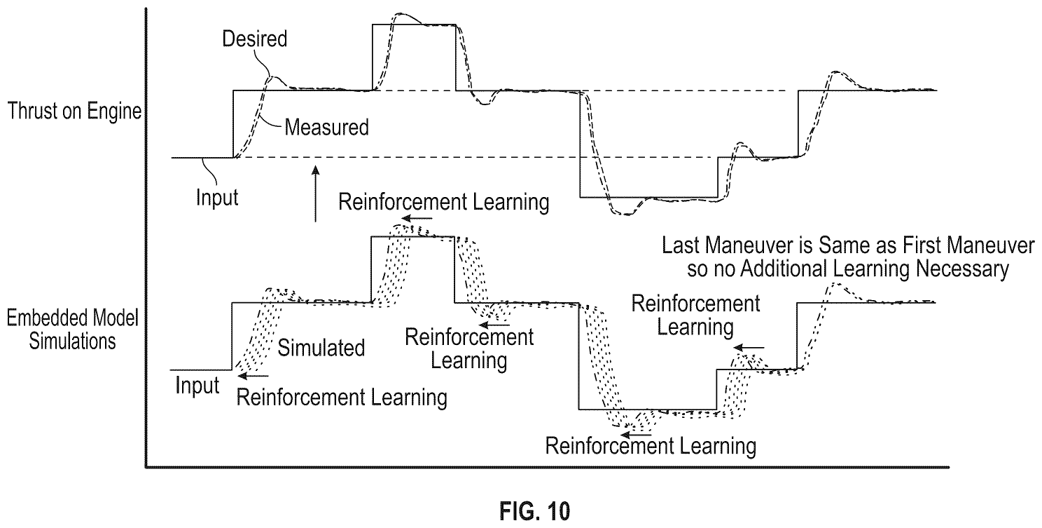

The graph in FIG. 10 is generated in response to sensor data obtained as the aircraft performs a plurality of maneuvers. FIG. 10 illustrates the results of how the disclosed system utilizes the embedded model 208 to improve the iterative loop and simulation capability to faster converge on a desired solution and how the disclosed system can adapt to different types of engine transients.

The aspects disclosed herein are examples of the disclosure and may be embodied in various forms. For instance, although certain aspects herein are described as separate aspects, each of the aspects herein may be combined with one or more of the other aspects herein. Specific structural and functional details disclosed herein are not to be interpreted as limiting, but as a basis for the claims and as a representative basis for teaching one skilled in the art to variously employ this disclosure in virtually any appropriately detailed structure.

The phrases “in an aspect,” “in aspects,” “in various aspects,” “in some aspects,” or “in other aspects” may each refer to one or more of the same or different aspects in accordance with this disclosure.

Approximating language, as used herein throughout the specification and claims, is applied to modify any quantitative representation that could permissibly vary without resulting in a change in the basic function to which it is related. Accordingly, a value modified by a term or terms, such as “about,” “approximately,” “generally,” and “substantially” is not to be limited to the precise value specified. In at least some instances, the approximating language may correspond to the precision of an instrument for measuring the value, or the precision of the methods or the machines for constructing the components and/or the systems or manufacturing the components and/or the systems. For example, the approximating language may refer to being within a one, two, four, ten, fifteen, or twenty percent margin in either individual values, range(s) of values and/or endpoints defining range(s) of values.

Further aspects of the present disclosure are provided by the subject matter of the following paragraphs.

A system for inversion control of turbine engines includes a processor; a memory including instructions which, when executed by the processor, cause the system at least to perform: simulating, by a state space model a simulated dynamic response based on the sensor data and a control input wherein the state space model includes one or more model parameters; inverting the state space model as output by the state space model; calculating a control gain based on the inverted state space model and the specified dynamic response; controlling the engine based at least in part on the calculated control gain; measuring a dynamic response; determining an error between a measured dynamic response and the specified dynamic response; correcting the state space model for the determined error based on updating the one or more model parameters using a machine learning network; and controlling the engine based at least in part on the corrected state space model.

The system according to any preceding clause, wherein when correcting the state space model, the instructions, when executed by the processor, further cause the system at least to perform: inputting the accessed sensor data and the control input into the machine learning network; determining, by the machine learning network, updates to the one or more model parameters of the state space model based on the determined error; and updating the state space model based on the determined updated one or more model parameters.

The system according to any preceding clause, wherein when correcting the state space model, the instructions, when executed by the processor, further cause the system at least to perform: inputting accessed sensor data and the control input into a tracked embedded model; generating an expected dynamic response of the engine by the tracked embedded model; inputting the accessed sensor data, the control input, and the expected dynamic response generated by the expected model into a machine learning network; determining, by the machine learning network, updates to the one or more model parameters of the state space model based on the determined error; and updating the state space model based on the determined updated one or more model parameters.

The system according to any preceding clause, wherein the instructions, when executed by the processor, further cause the system at least to perform: generating a chirp signal in a desired effector to output a response; and generating Bode responses based on the output response.

The system according to any preceding clause, wherein the instructions, when executed by the processor, further cause the system at least to perform: tuning the state space model to achieve the desired dynamic response of at least one of actuator dynamics or fuel system dynamics based on the generated Bode responses.

The system according to any preceding clause, wherein the instructions, when executed by the processor, further cause the system at least to perform: performing periodic direct system identification using the generated Bode responses; and generating a representation of plant dynamics of the engine based on the performed periodic direct system identification.

The system according to any preceding paragraph, wherein the instructions, when executed by the processor, further cause the system at least to perform: performing at least one of fault detection or preventative maintenance based on the generated representation of the plant dynamics of the engine.

The system according to any preceding clause, wherein the control input includes at least one of fuel flow, fan pitch, variable stator vanes, inlet guide vanes, or electric power.

The system according to any preceding clause, wherein the state space model is a linear state space model.

The system according to any preceding clause, wherein the one or more model parameters include partial derivatives.

A processor-implemented method for inversion control of turbine engines, includes: simulating, by a state space model a simulated dynamic response based on the sensor data and a control input wherein the state space model includes one or more model parameters; inverting the state space model as output by the state space model; calculating the engine based at least in part on the calculated gain; measuring a dynamic response; determining an error between a measured dynamic response and the inverted desired dynamic response; correcting the state space model for the determined error based on updating the one or more model parameters using a machine learning network; and controlling the engine based at least in part on the corrected state space model.

The method according to any preceding clause, wherein when correcting the state space model, the method further comprises: inputting accessed sensor data and the control input into a machine learning network; determining, by the machine learning network updates to the one or more model parameters of the state space model based on the determined error; and updating the state space model based on the determined updated one or more model parameters.

The method according to any preceding clause, wherein when correcting the state space model, the method further comprises: inputting accessed sensor data and the control input into a tracked embedded model; generating an expected dynamic response of the engine by the tracked embedded model; inputting the accessed sensor data, the control input, and the expected dynamic response generated by the expected model into a machine learning network; determining, by the machine learning network, updates to the one or more model parameters of the state space model based on the determined error; and updating the state space model based on the determined updated one or more model parameters.

The method according to any preceding clause, further comprising: generate a chirp signal in a desired effector to output a response; and generate Bode responses based on the output response.

The method according to any preceding clause, further comprising: tune the state space model to achieve the desired dynamic response of at least one of actuator dynamics or fuel system dynamics based on the generated Bode responses.

The method according to any preceding clause, further comprising: perform periodic direct system identification using the generated Bode responses; and generate a representation of plant dynamics of the engine based on the performed periodic direct system identification.

The method according to any preceding clause, further comprising: perform at least one of fault detection or preventative maintenance based on the generated representation of plant dynamics of the engine.

The method according to any preceding clause, wherein the control input includes at least one of fuel flow, fan pitch, variable stator vanes, inlet guide vanes, or electric power.

The method according to any preceding paragraph, wherein the one or more model parameters include partial derivatives.

A processor-implemented method for inversion control of turbine engines, includes: simulating, by a state space model a dynamic response based on the sensor data and a control input wherein the state space model includes one or more model parameters; inverting the state space model as output by the state space model; calculating a control gain based on the inverted state space model and the specified dynamic response; controlling the engine based at least in part on the calculated control gains; measuring a dynamic response; determining an error between a measured dynamic response and the specified dynamic response; correcting the state space model for the determined error based on updating the one or more model parameters using a machine learning network; and controlling the engine based at least in part on the corrected state space model.

It should be understood that the description herein is only illustrative of this disclosure. Various alternatives and modifications can be devised by those skilled in the art without departing from the disclosure. Accordingly, this disclosure is intended to embrace all such alternatives, modifications, and variances. The aspects described are presented only to demonstrate certain examples of the disclosure. Other elements, steps, methods, and techniques that are insubstantially different from those described above and/or in the appended claims are also intended to be within the scope of the disclosure.

What is claimed is:

1. A system for inversion control of turbine engines, the system comprising:
a processor; and
a memory including instructions which, when executed by the processor, cause the system at least to perform:
simulating, by a state space model, a simulated dynamic response based on a) sensor data indicative of an engine parameter and b) a control input, wherein the state space model includes one or more model parameters;
inverting the state space model;
calculating a control gain based on the inverted state space model and a specified dynamic response;
controlling the engine based at least in part on the calculated control gain;
measuring a dynamic response;
determining an error between the measured dynamic response and the specified dynamic response;
correcting the state space model for the determined error based on updating the one or more model parameters using a machine learning network; and
controlling the engine based at least in part on the corrected state space model.

2. The system of claim 1, wherein when correcting the state space model, the instructions, when executed by the processor, further cause the system at least to perform:
inputting accessed sensor data and the control input into the machine learning network;
determining, by the machine learning network, updates to the one or more model parameters of the state space model based on the determined error; and
updating the state space model based on the determined updated one or more model parameters.

3. The system of claim 1, wherein, when correcting the state space model, the instructions, when executed by the processor, further cause the system at least to perform:
inputting accessed sensor data and the control input into a tracked embedded model;
generating an expected dynamic response of the engine by the tracked embedded model;
inputting the accessed sensor data, the control input, and the expected dynamic response generated by the expected model into a machine learning network;
determining, by the machine learning network, updates to the one or more model parameters of the state space model based on the determined error; and
updating the state space model based on the determined updated one or more model parameters.

4. The system of claim 1, wherein the instructions, when executed by the processor, further cause the system at least to perform:
applying a chirp signal in a desired effector to output a response; and
generating Bode responses based on the output response.

5. The system of claim 4, wherein the instructions, when executed by the processor, further cause the system at least to perform:
tuning the state space model to achieve the specified dynamic response of at least one of actuator dynamics or fuel system dynamics based on the generated Bode responses.

6. The system of claim 4, wherein the instructions, when executed by the processor, further cause the system at least to perform:
performing periodic direct system identification using the generated Bode responses; and
generating a representation of plant dynamics of the engine based on the performed periodic direct system identification.

7. The system of claim 6, wherein the instructions, when executed by the processor, further cause the system at least to perform:
performing at least one of fault detection or preventative maintenance based on the generated representation of the plant dynamics of the engine.

8. The system of claim 1, wherein the control input includes at least one of fuel flow, fan pitch, variable stator vanes, inlet guide vanes, or electric power.

9. The system of claim 1, wherein the state space model is a linear state space model.

10. The system of claim 1, wherein the one or more model parameters include partial derivatives.

11. A processor-implemented method for inversion control of turbine engines, the method comprising:
simulating, by a state space model, a simulated dynamic response based on a) sensor data indicative of an engine parameter and b) a control input, wherein the state space model includes one or more model parameters;
inverting the state space model;
calculating a control gain based on the inverted state space model and the simulated dynamic response;
controlling the engine based at least in part on the calculated gain;
measuring a dynamic response;
determining an error between the measured dynamic response and the specified dynamic response;
correcting the state space model for the determined error based on updating the one or more model parameters using a machine learning network; and
controlling the engine based at least in part on the corrected state space model.

12. The processor-implemented method of claim 11, wherein when correcting the state space model, the method further comprises:
inputting accessed sensor data and the control input into a machine learning network;
determining, by the machine learning network updates to the one or more model parameters of the state space model based on the determined error; and
updating the state space model based on the determined updated one or more model parameters.

13. The processor-implemented method of claim 11, wherein when correcting the state space model, the method further comprises:
inputting accessed sensor data and the control input into a tracked embedded model;
generating an expected dynamic response of the engine by the tracked embedded model;
inputting the accessed sensor data, the control input, and the expected dynamic response generated by the expected model into a machine learning network;
determining, by the machine learning network, updates to the one or more model parameters of the state space model based on the determined error; and
updating the state space model based on the determined updated one or more model parameters.

14. The processor-implemented method of claim 11, further comprising:
applying a chirp signal in a desired effector to output a response; and
generating Bode responses based on the output response.

15. The processor-implemented method of claim 14, further comprising:
tuning the state space model to achieve the specified dynamic response of at least one of actuator dynamics or fuel system dynamics based on the generated Bode responses.

16. The processor-implemented method of claim 14, further comprising:
performing periodic direct system identification using the generated Bode responses; and
generating a representation of plant dynamics of the engine based on the performed periodic direct system identification.

17. The processor-implemented method of claim 14, further comprising:
performing at least one of fault detection or preventative maintenance based on the generated representation of plant dynamics of the engine.

18. The processor-implemented method of claim 11, wherein the control input includes at least one of fuel flow, fan pitch, variable stator vanes, inlet guide vanes, or electric power.

19. The processor-implemented method of claim 11, wherein the one or more model parameters include partial derivatives.

20. A non-transitory computer-readable storage medium in which is stored instructions for causing a processor to execute a processor-implemented method for inversion control of turbine engines, the method comprising:
simulating, by a state space model, a simulated dynamic response based on a) sensor data indicative of an engine parameter and b) a control input, wherein the state space model includes one or more model parameters;
inverting the state space model;
calculating a control gain based on the inverted state space model and the simulated dynamic response;
controlling the engine based at least in part on the calculated control gains;
measuring a dynamic response;
determining an error between the measured dynamic response and the specified dynamic response;
correcting the state space model for the determined error based on updating the one or more model parameters using a machine learning network; and
controlling the engine based at least in part on the corrected state space model.
